(19) United States
(12) Patent Application Publication
(10) Pub. No.: US 2017/0159167 A1
(43) Pub. Date: Jun. 8, 2017

(54) Thin Film Deposition Apparatus Having Plurality of Crucibles

(71) Applicant: SUNIC SYSTEM LTD., Suwon-si (Gyeonggi-do) (KR)

(72) Inventors: Young Man Oh, Yongin-si (Gyeonggi-do) (KR); Jae Soo Choi, Suwon-si (Gyeonggi-do) (KR); Soon Chul Lee, Suwon-si (Gyeonggi-do) (KR); Su Bin Kim, Seoul (KR); Myoung Soo Kim, Suwon-si (Gyeonggi-do) (KR); Young Jong Lee, Seongnam-si (Gyeonggi-do) (KR); Ki Min Song, Siheung-si (Gyeonggi-do) (KR); Young Shin Park, Suwon-si (Gyeonggi-do) (KR); Tae Won Seo, Suwon-si (Gyeonggi-do) (KR); Young Jin Bae, Suwon-si (Gyeonggi-do) (KR); Jeong Taek Kim, Seoul (KR); Jung Gyun Lee, Anyang-si (Gyeonggi-do) (KR)

(73) Assignee: SUNIC SYSTEM LTD., Suwon-si (Gyeonggi-do) (KR)

(21) Appl. No.: 15/324,110

(22) PCT Filed: Jul. 10, 2014
(86) PCT No.: PCT/KR2014/006227

§ 371 Date: Jan. 5, 2017

(30) Foreign Application Priority Data
Jul. 7, 2014 (KR) 10-2014-0084799
Jul. 7, 2014 (KR) 10-2014-0084800

(51) Int. Cl. C23C 14/24; C23C 14/54

(52) U.S. Cl. CPC C23C 14/243; C23C 14/542

(57) ABSTRACT

The present invention relates to a thin film deposition apparatus, which includes: a deposition chamber supporting a substrate therein; a plurality of crucibles keeping a deposition material to be deposited on the substrate; a distribution conduit having a plurality of coupling holes axially arranged to communicate with the crucibles, and spraying the deposition material evaporated from the crucibles through a plurality of nozzles formed through a top thereof; distribution conduit heaters independently installed and facing an outer side of the distribution conduit to heat the distribution conduit; crucible heaters heating the crucibles to evaporate the deposition material; and a top plate having an exit port corresponding to the nozzles and disposed over the distribution conduit. Accordingly, it is possible to reduce the height of the chamber by decreasing the height of the crucibles and to perform symmetric or asymmetric deposition by independently performing left/right deposition on a substrate.

### TECHNICAL FIELD

The present invention relates to a thin film deposition apparatus and, more particularly, to a thin film deposition apparatus having a plurality of crucibles, the apparatus being able to reduce the height of a chamber thereby decreasing the heights of crucibles and enabling symmetric or asymmetric deposition by independently performing left and right deposition.

### BACKGROUND ART

Deposition, which is a method generally used to manufacture semiconductor devices or flat display devices, is a process that deposits an organic substance, which is obtained by evaporating a deposition substance from the surface thereof by heating a crucible keeping the deposition substance, to a substrate in a high-vacuum chamber in order to coat the substrate with a deposition substance that is used for manufacturing semiconductor devices and flat display devices.

In general, deposition apparatuses include a vacuum chamber, a substrate support that is disposed in the chamber to support a substrate, and a distribution conduit that is disposed opposite to the substrate support to evaporate and supply a raw material to the substrate.

In upward deposition, the distribution conduit is disposed at the lower portion in the chamber, in detail, it is disposed opposite to a side of a substrate where a thin film is deposited and uniformly supplies and distributes an evaporated raw material to the side of the substrate through a plurality of paths.

A distribution conduit has been disclosed in Korean Patent No. 10-1057552 by the applicant(s), in which the distribution conduit is formed in cylindrical shape, a crucible keeping a deposition material is connected to the center portion of the distribution conduit, and a heater for heating the distribution conduit is provided.

Since the distribution conduit is connected to the crucible at the center portion, the configuration has a T-shape and the heater covers the outer side of the distribution conduit to heat a raw material passing through the distribution conduit.

In this related art, since the crucible is connected to the center portion of the distribution conduit and a deposition substance is supplied to the single crucible, it is required to increase the size of the crucible in order to supply a large amount of deposition substance.

Recently, since the areas of substrates are increased, in order to increase the sizes of flat display devices such as TV screens and improve productivity, there is a need for a deposition apparatus that can manufacture large-area substrates and it may be most important to develop an evaporation source for manufacturing large-area substrates in order to configure a deposition apparatus for manufacturing large-area substrates.

It is required to increase the capacity of a crucible for keeping a deposition substance in order to achieve an evaporation source for manufacturing large-area substrates, but when the length of the crucible is increased to increase the capacity of the crucible, the height of the chamber is also increased, so the entire deposition apparatus is increased in size and the manufacturing cost is increased.

Further, since the heater is wound directly around the outer side of the distribution conduit, it is required to separate the heater in order to replace the evaporation source, so it is very difficult to replace and repair broken parts.

### DISCLOSURE

### Technical Problem

The present invention has been made in an effort to solve the problems and an object of the present invention is to provide a thin film deposition apparatus that includes a plurality of crucibles and can be downsized by reducing the height of a chamber because it is possible to decrease the height of the crucible even though the same amount of deposition substance is deposited.

Further, another object of the present invention is to provide a thin film deposition apparatus that enables symmetric or asymmetric deposition on a substrate by independently controlling a deposition substance that is supplied through crucibles.

Further, another object of the present invention is to provide a thin film deposition apparatus that can simply separate a source upward by independently forming a heater for heating a crucible and a distribution conduit, and reduce and secure a space under a chamber.

Further, another object of the present invention is to provide a thin film deposition apparatus that allows for easily replacing and separating a heater when parts are broken because the heater is disposed at both sides of a distribution conduit.

### Technical Solution

In order to achieve the objects of the present invention, a thin film deposition apparatus includes: a deposition chamber supporting a substrate therein; a plurality of crucibles keeping a deposition material to be deposited on the substrate; a distribution conduit having a plurality of coupling holes axially arranged to communicate with the crucibles, and spraying the deposition material evaporated from the crucibles through a plurality of nozzles formed through a top thereof; distribution conduit heaters independently installed and facing an outer side of the distribution conduit to heat the distribution conduit; crucible heater heating the crucibles to evaporate the deposition material; and a top plate having an exit port corresponding to the nozzles and disposed over the distribution conduit.

Further, in order to achieve the objects of the present invention, a thin film deposition apparatus includes: a deposition chamber supporting a substrate therein; a plurality of crucibles keeping a deposition material to be deposited on the substrate; a plurality of distribution conduits coupled to the crucibles, respectively, and arranged in a line to spray an evaporated deposition material through a plurality of nozzles; distribution conduit heaters independently installed and facing an outer side of the distribution conduit to heat the distribution conduit; crucible heaters heating the crucibles to evaporate the deposition material; and a top plate having an exit port corresponding to the nozzles and disposed over the distribution conduit.

The distribution conduit heaters may be sheath heaters having an L-shaped cross-section to heat sides and a bottom of the distribution conduit.

The distribution conduit heaters may be disposed on both sides of the distribution conduit.

The top plate may be opened and closed, so when the top plate is opened, the distribution conduit may be separated upward to be replaced.

In the present invention, the top plate may slide to be opened and closed.

A reflector facing the top of the distribution conduit and reflecting heat from the distribution heater for heating may be disposed on a bottom of the top plate.

The reflectors may be stacked to efficiently reflect heat.

The distribution conduits may be disposed in parallel in the deposition chamber.

Nozzles of the distribution conduits at sides of the distribution conduits disposed in parallel may extend in a tangential direction of the distribution conduits to be positioned close to a center of the deposition chamber.

### Advantageous Effects

According to the thin film deposition apparatus of the present invention, it is possible to greatly reduce the length of crucibles even if the same amount of substance is deposited, so it is possible to reduce the height of a chamber and decrease the manufacturing cost.

Considering the height for attaching/detaching the crucibles, the entire height can be reduced by two times, as compared with the related art having a single crucible.

Further, symmetric or asymmetric deposition is possible by independently controlling left/right deposition on a substrate. In general, a nozzle cap is changed to adjust the amount of a deposition substance that is sprayed to a substrate, but it takes long time because it is required to stop the process, change the nozzle cap, and then make a vacuum state again. However, according to the present invention, the thicknesses of the left and right thin films on a substrate are independently controlled, so it is not required to change a nozzle cap, thereby reducing the process time.

Further, heaters for heating crucibles and distribution conduits are independently provided, so a source can be simply separated upward. Therefore, it is possible to reduce and ensure a space at a lower portion.

### DESCRIPTION OF DRAWINGS

FIG. 1 is a cross-sectional view showing the main configuration according to a first embodiment of a thin film deposition apparatus of the present invention.

FIG. 2 is a side cross-sectional view of FIG. 1.

FIG. 3 is a plan view showing the first embodiment of the present invention.

FIG. 4 is a cross-sectional view taken along line A-A of FIG. 3.

FIG. 5 is a cross-sectional view taken along line B-B of FIG. 3.

FIG. 6 is a cross-sectional view enlarging a distribution conduit shown in FIG. 5.

FIG. 7 is a cross-sectional view conceptually showing a deposition film that is deposited on a substrate by a thin film deposition apparatus of the present invention.

FIG. 8 is a cross-sectional view showing the main configuration according to a second embodiment of a thin film deposition apparatus of the present invention.

FIG. 9 is a side view of FIG. 8.

FIG. 10 is a plan view showing the second embodiment of the present invention.

FIG. 11 is a cross-sectional view taken along line A-A of FIG. 10.

FIG. 12 is a cross-sectional view taken along line B-B of FIG. 10.

FIG. 13 is a cross-sectional view enlarging a distribution conduit shown in FIG. 12.

FIG. 14 is a cross-sectional view conceptually showing a deposition film that is deposited on a substrate by a thin film deposition apparatus of the present invention.

FIG. 15 is a cross-sectional view showing another embodiment of an evaporation source of the present invention.

### BEST MODE

Hereinafter, embodiments of the present invention will be described in detail with reference to the accompanying drawings.

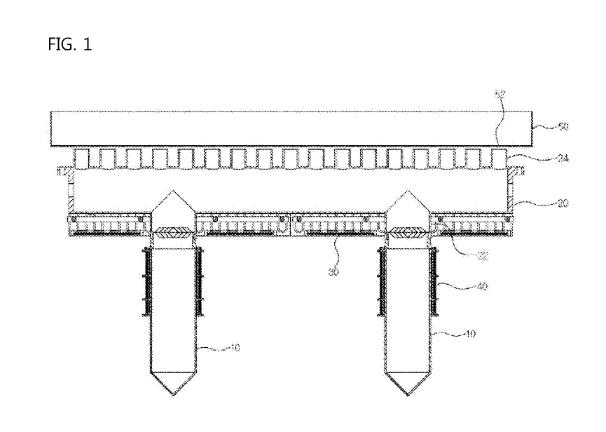

A thin film deposition apparatus of the present invention, as shown in FIGS. 1 and 8, largely includes a deposition chamber (not shown), crucibles 10 for keeping a deposition material, a distribution conduit 20 spraying a deposition material evaporated from the crucibles 10 to a substrate, heaters 30 and 40 for evaporating the deposition material by heating the distribution conduit 20 and the crucibles 10, and a top plate 50 disposed over the distribution conduit 20.

The present invention is characterized in that a plurality of crucibles 10 is provided.

The crucibles 10 are connected to the distribution conduit 20, so a plurality of crucibles 10 is connected to one distribution conduit 20.

Further, a plurality of crucibles 10 may be connected to each distribution conduit 20, so a plurality of distribution conduits 20 may be arranged in a line in a deposition chamber.

Mode for Invention

Hereinafter, embodiments of the present invention will be described in detail with reference to the accompanying drawings. First, in the specification, in giving reference numerals to components throughout the drawings, it should be noted that like reference numerals designate like components even though the components are shown in different drawings. The configuration and operation of the present invention shown and illustrated in the drawings are described through at least one embodiment, but the spirit, main configuration, and operation of the present invention are not limited thereto.

### First Embodiment

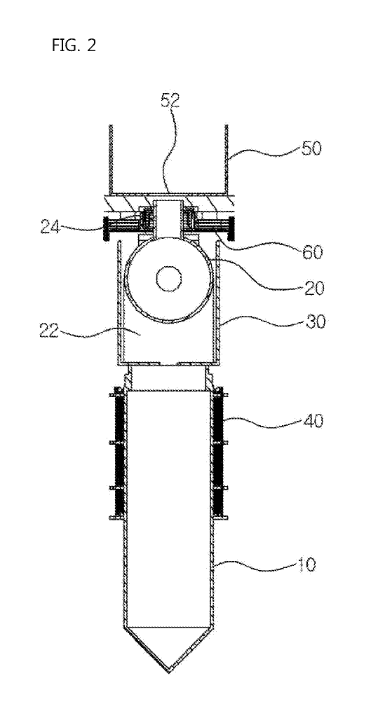

FIG. 1 is a cross-sectional view showing the main configuration according to a first embodiment of a thin film deposition apparatus of the present invention and FIG. 2 is a side cross-sectional view of FIG. 1.

A thin film deposition apparatus according to the present invention largely includes a deposition chamber (not shown), crucibles 10 for keeping a deposition material, a distribution conduit 20 spraying a deposition material evaporated from the crucibles 10 to a substrate, heaters 30 and 40 for evaporating the deposition material by heating the distribution conduit 20 and the crucibles 10, and a top plate 50 disposed over the distribution conduit 20.

The deposition chamber provides a predetermined reaction space for processing a substrate and may be formed in a shape corresponding to the shape of the substrate. For example, the deposition chamber may be formed in the shape of a cylinder or a rectangular box. Further, a gate (not shown) for putting the substrate into and out of the chamber and an exit port (not shown) for discharging gas in the chamber may be formed at a side of the chamber.

Meanwhile, the crucibles 10, which keep a deposition material to be deposited on a substrate and evaporate the deposition material by being heated by the heater 40, are heat resistant containers and are open at a side to discharge a heated deposition material to the outside.

The present invention is characterized in that a plurality of crucibles 10 is arranged in parallel. That is, the crucibles 10 are open upward and arranged in parallel in FIGS. 1 and 2.

The crucibles 10 communicate with the distribution conduit 20 and a plurality of coupling holes 22 communicating with the crucibles 10 is formed at the distribution conduit 20.

The coupling holes 22, as shown in FIGS. 1 and 2, are axially arranged in a line in the longitudinal direction of the distribution conduit 20.

A distribution conduit is connected with a single crucible at the center portion, thereby forming a T-shape in the related art, but according to the present invention, a plurality of coupling holes 22 is formed so that a plurality of crucibles 10 can be coupled to the distribution conduit 20, thereby forming a ‘TT’-shape.

According to the thin film deposition apparatus of the present invention, since a plurality of crucibles 10 is provided, it is possible to greatly reduce the length of the crucibles 10 for the same amount of substance to be deposited and to decrease the height of a chamber, so the manufacturing cost is reduced.

Considering the height for attaching/detaching the crucibles, the entire height can be reduced by two times as compared with the related art having a single crucible.

Although two coupling holes 22 are formed in the embodiment of the present invention, the present invention is not limited thereto and three or more coupling holes 22 may be formed, depending on the size of a substrate and the number of materials to be deposited, etc.

In this case, the coupling holes 22 may be symmetrically formed about the center line of a substrate, that is, the center of the distribution conduit 20 or may be formed with regular intervals. This is for uniformity of the film deposited on the substrate, and the positions and the gaps of the coupling holes 22 are not limited and may be changed in various ways, depending on the purposes of forming a thin film.

The distribution conduit 20 connected with the crucibles 10 can perform symmetric or asymmetric deposition by independently performing left/right control of a substrate. In this case, the crucibles 10 influence the deposition thicknesses at the left and right portions of a substrate, so it is required to expect and control the deposition thickness. Further, left/right symmetric deposition and asymmetric deposition at the left and right portions of the substrate are possible, so there is no need to change a nozzle cap.

In general, a nozzle cap is changed to adjust the amount of a deposition substance that is sprayed to a substrate, but it takes long time because it is required to stop the process, change the nozzle cap, and then make a vacuum state again. However, according to the present invention, the thicknesses of the left and right thin films on a substrate are independently controlled, so it is not required to change a nozzle cap, thereby reducing the process time.

A plurality of nozzles 24 is formed on the top of the distribution conduit 20, so the deposition material evaporated from the crucibles 10 is sprayed through the nozzles 24 at the upper portion.

On the other hand, the heaters 30 and 40 may be divided into a crucible heater 40 that heats the crucibles 10 to evaporate the deposition material in the crucibles 10 and a distribution conduit heater 30 that evaporates a deposition material by heating the distribution conduit 20. Obviously, the distribution conduit heaters 30 and the crucible heaters 40 may be integrated, but in order to explain the difference of the shapes in the present invention, for the sake of convenience, the heaters for heating the distribution conduit 20 are referred to as the distribution conduit heaters 30 and the heaters for heating the crucibles 10 are referred to as the crucible heaters 40.

The distribution conduit heaters 30 and the crucible heaters 40 are independently disposed on the outer sides of the distribution conduit 20 and the crucibles 10.

The distribution conduit heaters 30 and the crucible heaters 40 may be sheath heaters including a heating block and a heating wire. That is, a heat line is disposed in a heating block and generates heat when power is supplied from the outside, thereby heating the distribution conduit 20 and the crucibles 10.

In the present invention, the distribution conduit heaters 30 may be sheath heaters having an L-shaped cross-section, as shown in FIG. 2, to heat the sides and the bottom of the distribution conduit 20.

In this case, the distribution conduit heaters 30 are, as shown in FIG. 2, disposed on both sides of the distribution conduit 20 to uniformly heat the distribution conduit 20.

Further, the crucible heaters 40 may be disposed such that the heating blocks cover the outer sides of the crucibles 10.

The crucible heaters 40 are provided to heat the crucibles 10, respectively.

That is, in the crucibles 10, various kinds of organic substances may be evaporated or sublimated by heat or the same kinds of organic substance may be evaporated or sublimated by heat.

The crucible heaters 40 for heating organic substances are provided for the crucibles 10, respectively, and they may be operated at different temperatures to evaporate or sublimate various kinds of organic substances by heating them. For example, in order to evaporate a host organic substance in one crucible 10 and a dopant organic substance in another crucible 10, it may be possible to heat a host organic substance and a dopant organic substance that have different evaporation points at optimum temperatures and adjust the diffusion speeds of the organic substances so that the substances can be deposited on a substrate with desired concentrations.

On the other hand, the top plate 50 is disposed over the distribution conduit 20 in the present invention. The exit port 52 corresponding to the nozzles 24 is formed in the top plate 50 so that the deposition material evaporated in the distribution conduit 20 can be sprayed to a substrate.

The top plate 50 may be opened and closed. That is, by opening the top plate 50, it is possible to take the distribution conduit 20 out upward to replace it. Since the heaters 30 and 40 for heating the crucibles 10 and the distribution conduit 20 are independently formed in the present invention, it is possible to attach/detach a source without separating the heaters 30 and 40 when replacing the source and it is possible to open the top plate 50 and simply separate a source upward.

In the present invention, the top plate 50 may be formed to slide for opening/closing. For example, by installing rollers on sides of the top plate 50 and forming rails for the rollers to slide on, it is possible to slide the top plate 50 to open/close it. However, the present invention is not limited thereto and the top plate 50 may be opened/close in ways and by structures well known in the art.

Meanwhile, a reflector 60 that faces the top of the distribution conduit 20 and can reflect heat from the distribution conduit heaters 30 for heating is disposed on the bottom of the top plate 50. The distribution conduit heaters 30 have an L-shape and heat the sides and the bottom of the distribution conduit 20, so the reflector 60 that can reflect the heat from the distribution conduit heaters 30 for heating is disposed on the bottom of the top plate 50 in order to reinforce the structure without a heater on the top of the distribution conduit 20.

In this case, a plurality of reflectors 60 may be stacked to efficiently reflect heat.

According to the present invention including the distribution conduit heaters 30 and the reflectors 60, heating zones for heating the distribution conduit 20 are formed so that the deposition material can be stably evaporated through the distribution conduit 20.

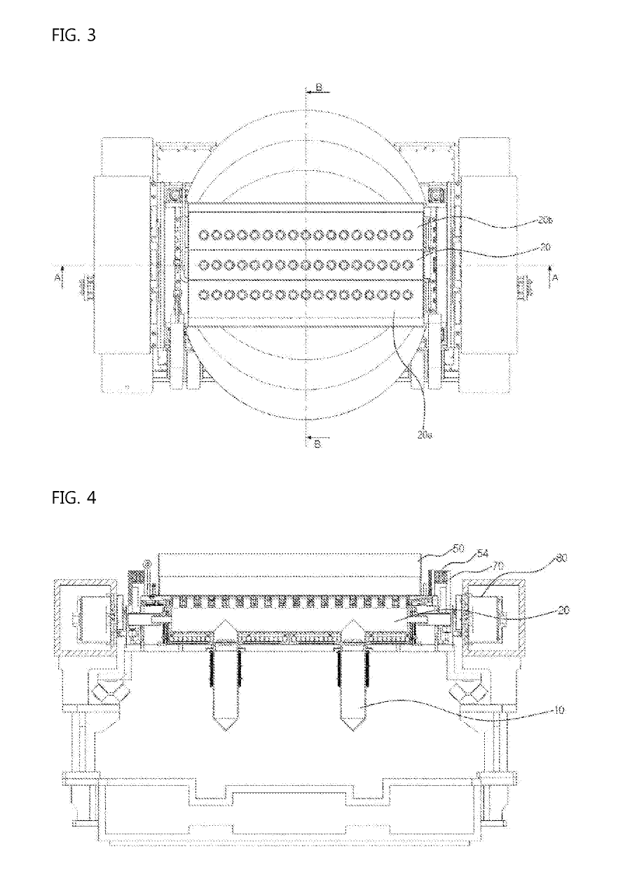

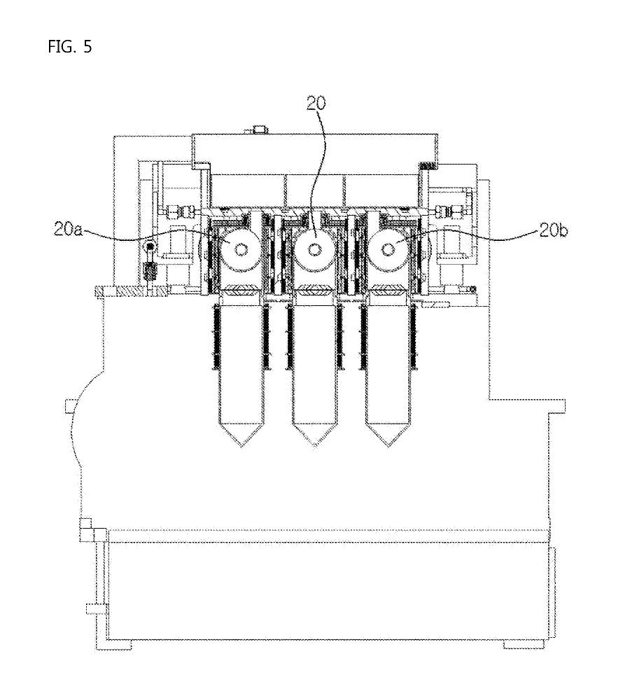

FIG. 3 is a plan view showing an embodiment to which the thin film deposition apparatus of the present invention is applied, FIG. 4 is a cross-sectional view taken along line A-A of FIG. 3, and FIG. 5 is a cross-sectional view taken along line B-B of FIG. 3.

According to the thin film deposition apparatus of the present invention, as shown in FIG. 3, a plurality of distribution conduits 20, 20a, and 20b may be disposed in one deposition chamber. Although three distribution conduits 20, 20a, and 20b are disposed in the thin film deposition apparatus provided as an embodiment of the present invention, the present invention is not limited thereto and the number of the distribution conduits may be changed, if necessary.

According to the thin film deposition apparatus, as described above, a plurality of crucibles 10 is connected to each of the distribution conduits 20, 20a, and 20b. If two crucibles 10 are installed for each of the three distribution conduits 20, 20a, and 20b provided as an embodiment, a total of six crucibles 10 are installed.

A top plate 50 is disposed over the distribution conduit 20. Sliding rails 70 are disposed at both sides of the top plate 50 so that the top plate 50 can be slid by rollers 54 coupled to the top plate 50.

Accordingly, it is possible to open the top plate 50 by sliding it and then remove the distribution conduit 20 upward.

Further, sensors 80 that sense the thickness of a deposition film by sensing the amount of a deposition material may be disposed at both longitudinal ends of the distribution conduit 20.

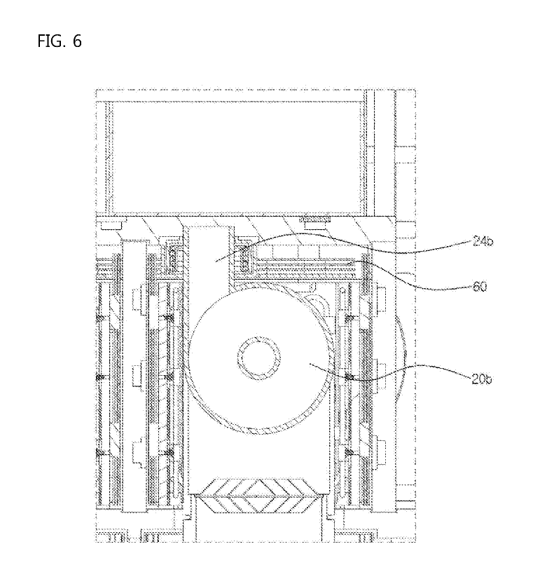

On the other hand, FIG. 6 is a cross-sectional view enlarging a distribution conduit of FIG. 5. When a plurality of distribution conduits 20, 20a, and 20b is installed, nozzles 24a and 24b of the distribution conduits 20a and 20b at both sides of the distribution conduits may extend in a tangential direction of the distribution conduits 20a and 20b to be positioned close to the center of the deposition chamber.

That is, the distribution conduit 20b shown in FIG. 6 is the right one in FIG. 5, so the nozzles 24b may extend in the left tangential direction of the distribution conduit 20b to be positioned close to the center of the deposition chamber. On the other hand, as for the distribution conduit 20a at the left side in FIG. 5, the nozzles 24a may extend in the right tangential direction of the distribution conduit 20a to be positioned close to the center of the deposition chamber.

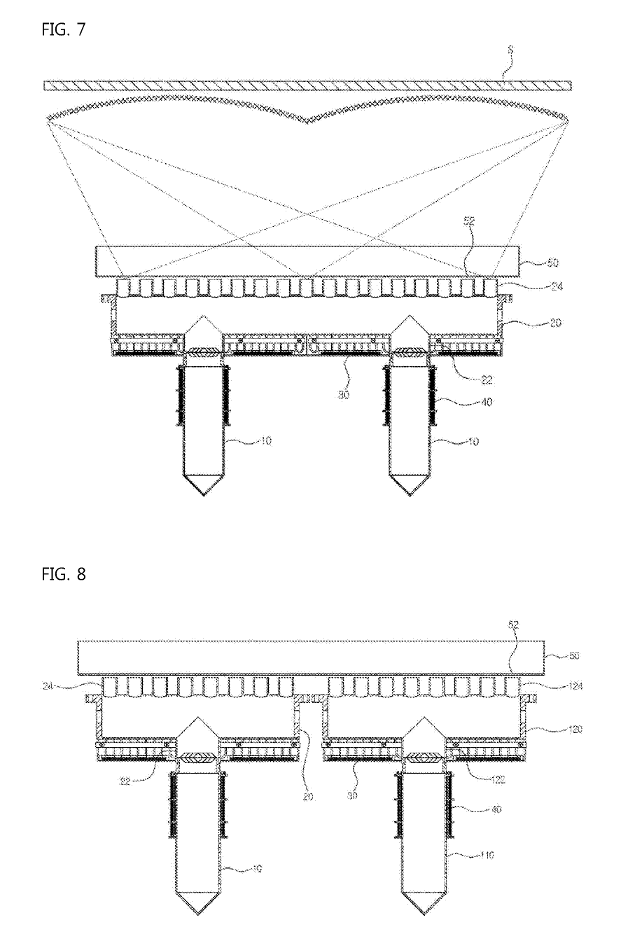

FIG. 7 is a cross-sectional view conceptually showing a deposition film that is deposited on a substrate by the thin film deposition apparatus of the present invention. The thin film deposition apparatus of the present invention evaporates a deposition material through a plurality of crucibles 10, so it is possible to independently control the thickness of the deposition film on the left and right portions of a substrate S by individually controlling the crucibles 10, whereby symmetric or asymmetric deposition is possible.

### Second Embodiment

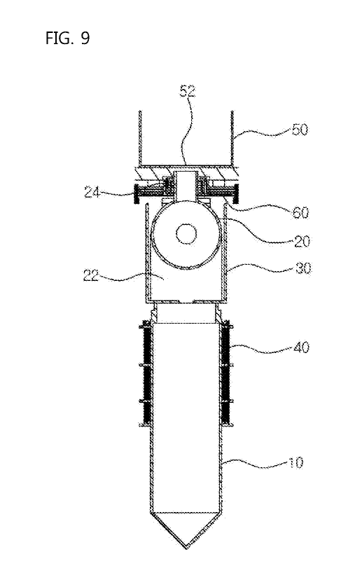

FIG. 8 is a cross-sectional view showing the main configuration according to a second embodiment of a thin film deposition apparatus of the present invention and FIG. 9 is a side cross-sectional view of FIG. 8.

A thin film deposition apparatus according to a second embodiment of the present invention largely includes a deposition chamber (not shown), crucibles 10 and 110 for keeping a deposition material, distribution conduits 20 and 120 spraying a deposition material evaporated from the crucibles 10 and 110 to a substrate, heaters 30 and 40 for evaporating the deposition material by heating the distribution conduits 20 and 120 and the crucibles 10 and 110, and a top plate 50 disposed over the distribution conduits 20 and 120.

The second embodiment of the present invention is characterized in that a plurality of distribution conduits 20 and 120 that is coupled to the crucibles 10 and 110 and sprays an evaporated deposition material is arranged in parallel. That is, as shown in FIG. 8, the distribution conduits 20 and 120 coupled to the crucibles 10 and 110 through coupling holes 22 and 122 are arranged in a line in the longitudinal direction inside the deposition chamber.

According to the thin film deposition apparatus of the present invention, since a plurality of crucibles 10 and 110 is provided, it is possible to greatly reduce the length of the crucibles 10 and 110 for the same amount of substance to be deposited and to decrease the height of a chamber, so the manufacturing cost is reduced.

Considering the height for attaching/detaching the crucibles, the entire height can be reduced by two times as compared with the related art having a single crucible.

Although two distribution conduits 20 and 120 are provided in the embodiment of the present invention, the present invention is not limited thereto and three or more distribution conduits 20 and 120 may be installed, depending on the size of a substrate and the number of materials to be deposited, etc.

In this case, the distribution conduits 20 and 120 may be symmetrically arranged about the center line of a substrate or may be arranged with a predetermined gap therebetween. This is for uniformity of the film deposited on the substrate, and the positions and the gaps of the distribution conduits 20 and 120 are not limited and may be changed in various ways, depending on the purposes of forming a thin film.

The distribution conduits 20 and 120 can perform symmetric or asymmetric deposition by independently performing left/right control of a substrate. In this case, the crucibles 10 and 110 influence the deposition thicknesses at the left and right portions of a substrate, so it is required to expect and control the deposition thickness. Further, left/right symmetric deposition and asymmetric deposition at the left and right portions of the substrate are possible, so there is no need to change a nozzle cap.

In general, a nozzle cap is changed to adjust the amount of a deposition substance that is sprayed to a substrate, but it takes long time because it is required to stop the process, change the nozzle cap, and then make a vacuum state again. However, according to the present invention, the thicknesses of the left and right thin films on a substrate are independently controlled, so it is not required to change a nozzle cap, thereby reducing the process time.

A plurality of nozzles 24 and 124 is formed on the top of the distribution conduit 20 and 120, so the deposition material evaporated from the crucibles 10 and 110 is sprayed through the nozzles 24 and 124 at the upper portion.

On the other hand, as in the second embodiment described above, the heaters 30 and 40 may be divided into crucible heaters 40 that heat the crucibles 10 and 110 to evaporate the deposition material in the crucibles 10 and 110 and distribution conduit heaters 30 that evaporate a deposition material by heating the distribution conduits 20 and 120. Obviously, the distribution conduit heater 30 and the crucible heaters 40 may be integrated, but in order to explain the difference of the shapes in the present invention, for the sake of convenience, the heaters for heating the distribution conduit 20 and 120 are referred to as the distribution conduit heaters and the heaters for heating the crucibles 10 and 110 are referred to as the crucible heaters 40.

The distribution conduit heaters 30 and the crucible heaters 40 are independently disposed on the outer sides of the distribution conduits 20 and 120 and the crucibles 10 and 110.

The distribution conduit heater 30 and the crucible heater 40 may be sheath heaters including a heating block and a heating wire. That is, a heat line is disposed in a heating block and generates heat when power is supplied from the outside, thereby heating the distribution conduit 20 and the crucibles 10.

In the present invention, the distribution conduit heaters 30 may be sheath heaters having an L-shaped cross-section, as shown in FIG. 2, to heat the sides and the bottom of the distribution conduit 20.

In this case, the distribution conduit heaters 30 are, as shown in FIG. 9, disposed on both sides of the distribution conduit 20 to uniformly heat the distribution conduit 20.

Further, the crucible heaters 40 may be disposed such that the heating blocks cover the outer sides of the crucibles 10.

The crucible heaters 40 are provided to heat the crucibles 10 and 110, respectively.

That is, in the crucibles 10 and 110, various kinds of organic substances may be evaporated or sublimated by heat or the same kinds of organic substance may be evaporated or sublimated by heat.

The crucible heaters 40 for heating organic substances are provided for the crucibles 10 and 110, respectively, and they may be operated at different temperatures to evaporate or sublimate various kinds of organic substances by heating them. For example, in order to evaporate a host organic substance in one crucible 10 and a dopant organic substance in another crucible 110, it may be possible to heat a host organic substance and a dopant organic substance that have different evaporation points at optimum temperatures and adjust the diffusion speeds of the organic substances so that the substances can be deposited on a substrate with desired concentration.

Meanwhile, in the second embodiment, similarly, a top plate 50 is disposed over the distribution conduits 20 and 120 and a reflector 60 that faces the top of the distribution conduits 20 and 120 and can reflect heat from the distribution conduit heater 30 for heating is disposed on the bottom of the top plate 50.

According to the present invention including the distribution conduit heaters 30 and the reflector 60, heating zones for heating the distribution conduits 20 and 120 are formed so that the deposition material can be stably evaporated through the distribution conduits 20 and 120.

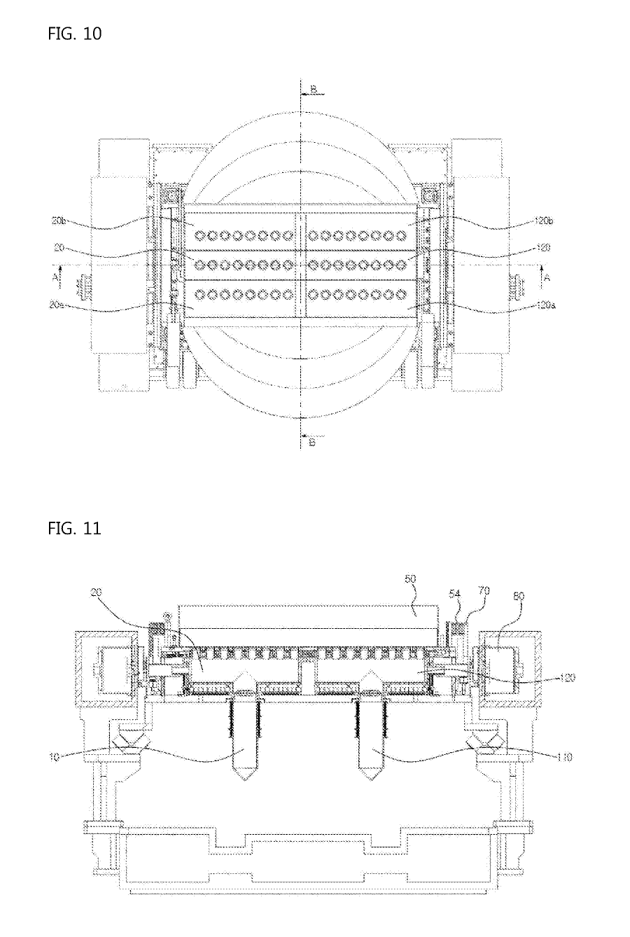

According to the thin film deposition apparatus of the present invention, as shown in FIG. 10, a plurality of distribution conduits 20 and 120 may be disposed in parallel in one deposition chamber. If the distribution conduits 20 and 120 are arranged in parallel in an X direction in the above description, the distribution conduits 20 and 120 arranged in parallel in the X direction are arranged in parallel in a Y direction too.

Although distribution conduits disposed in parallel in the axial direction are arranged in three lines, so a total of six distribution conduits 20, 20a, 20b, 120, 120a, and 120b are disposed in the thin film deposition apparatus provided as an embodiment of the present invention, the present invention is not limited thereto and the number of the distribution conduits may be changed, if necessary.

As described above, in the thin film deposition apparatus, the crucibles 10 and 110 communicate with the distribution conduits 20, 20a, 20b, 120, 120a, and 120b, so a total of six crucibles 10 and 110 are installed.

A top plate 50 is disposed over the distribution conduits 20, 20a, 20b, 120, 120a, and 120b. Sliding rails 70 are disposed at both sides of the top plate 50 so that the top plate 50 can be slid by rollers 54 coupled to the top plate 50.

Accordingly, it is possible to open the top plate 50 by sliding it and remove the distribution conduits 20, 20a, 20b, 120, 120a, and 120b upward.

Further, sensors 80 that sense the thickness of a deposition film by sensing the amount of a deposition material may be disposed at both longitudinal ends of the distribution conduits 20, 20a, 20b, 120, 120a, and 120b.

According to the present invention, since the heaters 30 and 40 are installed independently from the distribution conduits 20, 20a, 20b, 120, 120a, and 120b, it is very simple to replace them, even if there are many distribution conduits 20, 20a, 20b, 120, 120a, and 120b, so it is possible to greatly reduce the time for processes for replacing or repairing.

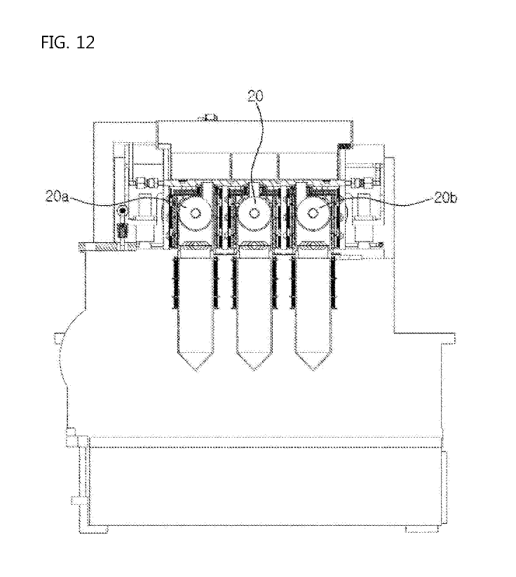

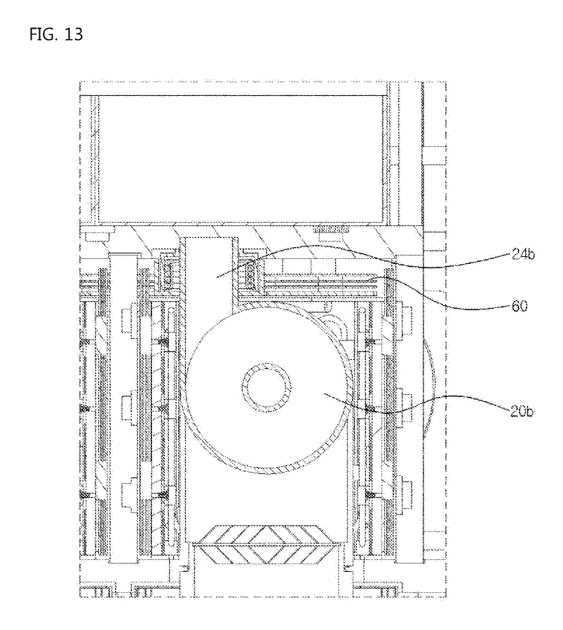

On the other hand, FIG. 13 is a cross-sectional view enlarging a distribution conduit of FIG. 12. When a plurality of distribution conduits 20, 20a, 20b, 120, 120a, and 120b is installed, nozzles 24a and 24b of the distribution conduits 20a and 20b at both sides of the distribution conduits may extend in a tangential direction of the distribution conduits 20a and 20b to be positioned close to the center of the deposition chamber.

That is, the distribution conduit 20b shown in FIG. 13 is the right one in FIG. 12, so the nozzles 24b may extend in the left tangential direction of the distribution conduit 20b to be positioned close to the center of the deposition chamber. On the other hand, as for the distribution conduit 20a at the left side in FIG. 12, the nozzles 24a may extend in the right tangential direction of the distribution conduit 20a to be positioned close to the center of the deposition chamber.

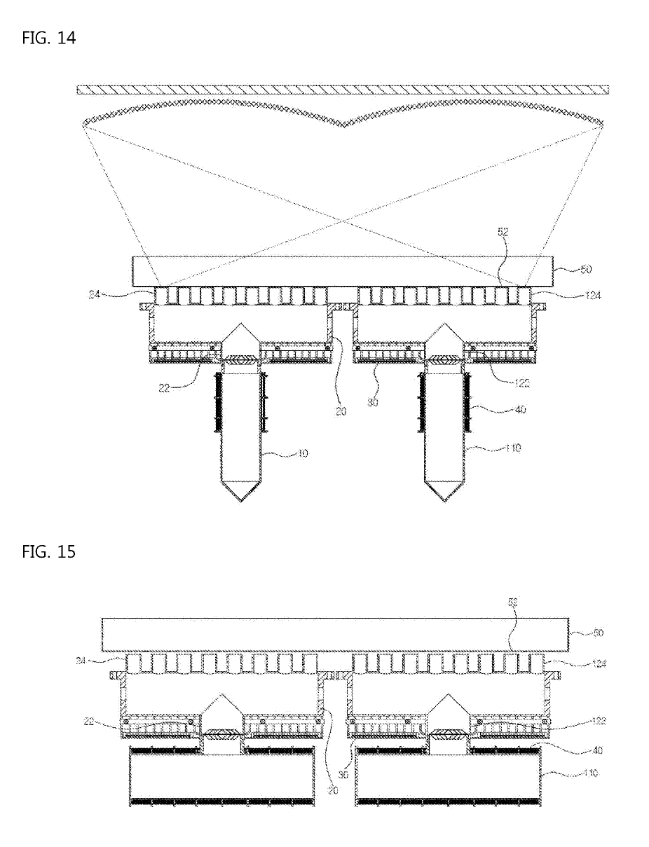

FIG. 14 is a cross-sectional view conceptually showing a deposition film that is deposited on a substrate by the thin film deposition apparatus of the present invention. The thin film deposition apparatus of the present invention evaporates a deposition material through a plurality of crucibles 10, so it is possible to independently control the thickness of the deposition film on the left and right portions of a substrate S by individually controlling the crucibles 10, whereby symmetric or asymmetric deposition is possible.

FIG. 15 is a cross-sectional view showing another embodiment of an evaporation source of the present invention.

As shown in FIG. 15, the crucibles 10 and 110 may extend not in the height direction of the chamber (upward), but in the longitudinal direction of the distribution conduits 20 and 120.

In this case, the crucible heater 40 may be laterally disposed to heat the cylindrical outer sides of the crucibles 10 and 110.

According to the thin film deposition apparatus of the present invention, since the crucibles 10 and 110 are laterally disposed, it is possible to greatly reduce the height of the crucibles 10 and 110 and to decrease the height of a chamber, so the manufacturing cost is reduced.

The above description is an example that explains the spirit of the present invention and may be changed and modified in various ways without departing from the basic features of the present invention by those skilled in the art. Accordingly, the embodiment described herein are provided not to limit, but to explain the spirit of the present invention and the spirit and the scope of the present invention are not limited by the embodiments. The protective range of the present disclosure should be construed on the basis of claims and all the technical spirits in the equivalent range should be construed as being included in the scope of the right of the present disclosure.

1. A thin film deposition apparatus comprising:
a deposition chamber supporting a substrate therein;
a plurality of crucibles keeping a deposition material to be deposited on the substrate; a distribution conduit having a plurality of coupling holes axially arranged to communicate with the crucibles, and spraying the deposition material evaporated from the crucibles through a plurality of nozzles formed through a top thereof;
distribution conduit heaters independently installed and facing an outer side of the distribution conduit to heat the distribution conduit;
crucible heaters heating the crucibles to evaporate the deposition material; and a top plate having an exit port corresponding to the nozzles and disposed over the distribution conduit.

2. A thin film deposition apparatus comprising:
a deposition chamber supporting a substrate therein;
a plurality of crucibles keeping a deposition material to be deposited on the substrate; a plurality of distribution conduits coupled to the crucibles, respectively, and arranged in a line to spray an evaporated deposition material through a plurality of nozzles;
distribution conduit heaters independently installed and facing an outer side of the distribution conduit to heat the distribution conduit;
crucible heaters heating the crucibles to evaporate the deposition material; and
a top plate having an exit port corresponding to the nozzles and disposed over the distribution conduit.

3. The apparatus of claim 1, wherein the distribution conduit heaters are sheath heaters having an L-shaped cross-section to heat sides and a bottom of the distribution conduit.

4. The apparatus of claim 3, wherein the distribution conduit heaters are disposed on both sides of the distribution conduit.

5. The apparatus of claim 1, the top plate can be opened and closed, so when the top plate is opened, the distribution conduit can be separated upward to be replaced.

6. The apparatus of claim 5, wherein the top plate slides to be opened and closed.

7. The apparatus of claim 1, wherein a reflector facing the top of the distribution conduit and reflecting heat from the distribution conduit heater for heating is disposed on a bottom of the top plate.

8. The apparatus of claim 7, wherein the reflectors are stacked.

9. The apparatus of claim 1, wherein the distribution conduits are disposed in parallel in the deposition chamber.

10. The apparatus of claim 9, wherein nozzles of the distribution conduits at sides of the distribution conduits disposed in parallel extend in a tangential direction of the distribution conduits to be positioned close to a center of the deposition chamber.

11. The apparatus of claim 2, wherein the distribution conduit heaters are sheath heaters having an L-shaped cross-section to heat sides and a bottom of the distribution conduit.

12. The apparatus of claim 2, the top plate can be opened and closed, so when the top plate is opened, the distribution conduit can be separated upward to be replaced.

13. The apparatus of claim 2, wherein a reflector facing the top of the distribution conduit and reflecting heat from the distribution conduit heater for heating is disposed on a bottom of the top plate.

14. The apparatus of claim 2, wherein the distribution conduits are disposed in parallel in the deposition chamber.

15. The apparatus of claim 11, wherein the distribution conduit heaters are disposed on both sides of the distribution conduit.

16. The apparatus of claim 12, wherein the top plate slides to be opened and closed.

17. The apparatus of claim 13, wherein the reflectors are stacked.

18. The apparatus of claim 14, wherein nozzles of the distribution conduits at sides of the distribution conduits disposed in parallel extend in a tangential direction of the distribution conduits to be positioned close to a center of the deposition chamber.
